(19) United States
(12) Patent Application Publication
(10) Pub. No.: US 2020/0014161 A1
(43) Pub. Date: Jan. 9, 2020

(54) Dual-Interface Reversible Plug-in Power Source and Data Docking Station

(71) Applicant: GUANGDONG GOPOD GROUP CO., LTD., Shenzhen (CN)

(72) Inventor: Zhuowen Liao, Shenzhen (CN)

(21) Appl. No.: 16/574,066

(22) Filed: Sep. 17, 2019

Related U.S. Application Data
(63) Continuation of application No. PCT/CN2017/093572, filed on Jul. 19, 2017.

(30) Foreign Application Priority Data
Apr. 27, 2017 (CN) 201720469643.X

(51) Int. Cl. H01R 31/06; H01R 13/506; H05K 1/18; H05K 5/00

(52) U.S. Cl. CPC H01R 31/065; H01R 13/506; H05K 1/18; H05K 2201/10522; H05K 5/006; H05K 2201/10189; H05K 5/0052

(57) ABSTRACT

Disclosed is a dual-interface reversible plug-in power source and data docking station (10), comprising a case (11) and a circuit board (12), wherein the circuit board is provided with a first side and a second side; the first side is provided with a first Type-C male interface (131) and a second Type-C male interface (132); and the second side is provided with a second Type-C female interface (141) and a second Type-C female interface (142), and the second side is further provided with an interface group (15). If a MacbookPro is to be connected, the first Type-C male interface and the second Type-C male interface can be respectively connected to two interfaces of the MacbookPro, and at the same time, the first Type-C female interface and the second Type-C female interface are provided for extension.

### CROSS REFERENCE TO RELATED APPLICATIONS

The present application is a Continuation Application of PCT Application No. PCT/CN2017/093572 filed on Jul. 19, 2017, which claims the benefit of Chinese Patent Application No. 201720469643.X filed on Apr. 27, 2017. All the above are hereby incorporated by reference.

### TECHNICAL FIELD

The present invention belongs to the technical field of integrated design for charging and data transmission, and more particularly, relates to a dual-interface reversible plug-in power source and data docking station.

### BACKGROUND ART

In recent years, with rapid development of electronic technology and integrated circuit application design, charging and data products have become field application products for consumer groups. The power source and data docking station is a design application that can be implemented to simultaneously complete charging and data communication between digital products, so that devices become more and more compatible among application fields. However, existing power source and data docking stations still have the following problem: the power source and data docking station is only provided with one Type-C interface for data transmission, and if the power source and data docking station is connected to one of interfaces of a MacbookPro (an Apple's product) through the Type-C interface (i.e., a common USB Type-C interface), it will block the other interface of the MacbookPro, so that one interface of the MacbookPro is not fully usable.

### TECHNICAL PROBLEM

An object of the present invention is to provide a dual-interface reversible plug-in power source and data docking station, which aims to solve the problem of failing to fully utilize two interfaces of a MacbookPro when the existing power source and data docking station is connected to an interface of the MacbookPro.

### SOLUTIONS TO THE PROBLEM

### Technical Solutions

In order to achieve the above object, the technical solution used in the present invention is as follows: a dual-interface normal/plug-in power source and data docking station is provided, comprising: a case having an inner cavity and a circuit board arranged in the inner cavity, wherein the circuit board is provided with a first side and a second side opposite to or adjacent to the first side; the first side is provided with a first Type-C male interface configured to be connected to one of interfaces of a MacbookPro and a second Type-C male interface which is arranged side by side at an interval from the first Type-C male interface and configured to be connected to the other interface of the MacbookPro; the second side is provided with a first Type-C female interface and a second Type-C female interface which are respectively opposite to the first Type-C male interface and the second Type-C male interface, and the second side is further provided with an interface group for charging and/or data transmission for an external electronic product; the first Type-C male interface and the second Type-C male interface are exposed outside the case; and the case is provided with a plurality of openings respectively corresponding to the first Type-C female interface, the second Type-C female interface and the interface group on a one-to-one basis.

Further, the interface group comprises a USB interface, an HDMI interface configured to be connected to a display device, an SD card interface for reading an SD card, and a Micro SD card interface for reading a Micro SD card.

Further, the case comprises a bottom case, which comprises a bottom portion and a side wall extending along the periphery of the bottom portion, wherein the bottom portion and the side wall are enclosed to form the inner cavity, an upper end of the side wall is detachably connected to an upper cover, and the openings are provided in the side wall.

Further, a fixing frame is arranged in the inner cavity, and the circuit board is installed on the fixing frame.

Further, the fixing frame comprises a bottom plate and a side frame wall extending along the periphery of the bottom plate, wherein the side frame wall is provided with a plurality of notches respectively corresponding to the opening on a one-to-one basis, and the circuit board is installed in a space enclosed by the bottom plate and the side frame wall.

Further, the periphery of the upper cover is provided with a plurality of barbs arranged at intervals, and the side frame wall is provided with a plurality of barb slots respectively corresponding to and matching the barbs on a one-to-one basis.

Further, the number of the USB interfaces is set to at least one.

Further, the case has an elongated shape.

Further, a main control chip, a high-definition decoding chip, a power source management chip, a high-frequency transformer and a power component are arranged at intervals on the circuit board.

Further, the interface group further comprises a VGA interface, a DVI interface, a DP interface, a Mini DP interface or a network interface.

Further, the type of the USB interface is USB2.0, USB3.0, USB-C or USB3.1.

Further, the first Type-C male interface, the second Type-C male interface, the first Type-C male interface and the second Type-C male interface are all in bidirectional transmission.

Further, the first Type-C female interface is connected to a device with Type-C interfaces and configured to support USB data transmission, and the second Type-C female interface is connected to the device with Type-C interfaces and configured to support a PD charging function.

### BENEFICIAL EFFECTS OF THE INVENTION

### Beneficial Effects

The beneficial effects of the dual-interface reversible plug-in power source and data docking station provided by the invention are as follows: compared with the prior art, when the dual-interface reversible plug-in power source and data docking station described above is configured to be connected to a MacbookPro, the first Type-C male interface and the second Type-C male interface located on the first side of the circuit board can be respectively connected to the two interfaces of the MacbookPro, and the first Type-C male interface and the second Type-C male interface can be connected to the two interfaces of the MacbookPro regardless of whether normal plug-in or reverse plug-in is used; and moreover, since the two interfaces of the MacbookPro are blocked by the dual-interface reversible plug-in power source and data docking station so that user cannot use the two original interfaces of the MacbookPro for charging, video communication or data communication, the dual-interface reversible plug-in power source and data docking station is provided with the first Type-C female interface and the second Type-C female interface for extension while converting the first Type-C male interface and the second Type-C male interface into other interfaces such as the interface group, and is externally connected to an external electronic product through the first Type-C female interface and the second Type-C female interface for charging, video communication or data communication. In this way, when the dual-interface reversible plug-in power source and data docking station described above is used by a user for charging, video communication or data communication for an external electronic product, it not only has a new Type-C female interface function and is also compatible with the old interface function, e.g., using the interface group.

### BRIEF DESCRIPTION OF THE ACCOMPANYING DRAWINGS

### Brief Description of the Drawings

In order to illustrate the technical solutions in the embodiments of the present invention more clearly, a brief introduction to the figures to be used in the description of the embodiments or the prior art will be provided below. Obviously, the drawings in the following description show merely some embodiments of the present invention, and those of ordinary skilled in the art would have derived other drawings from these drawings without any creative effort.

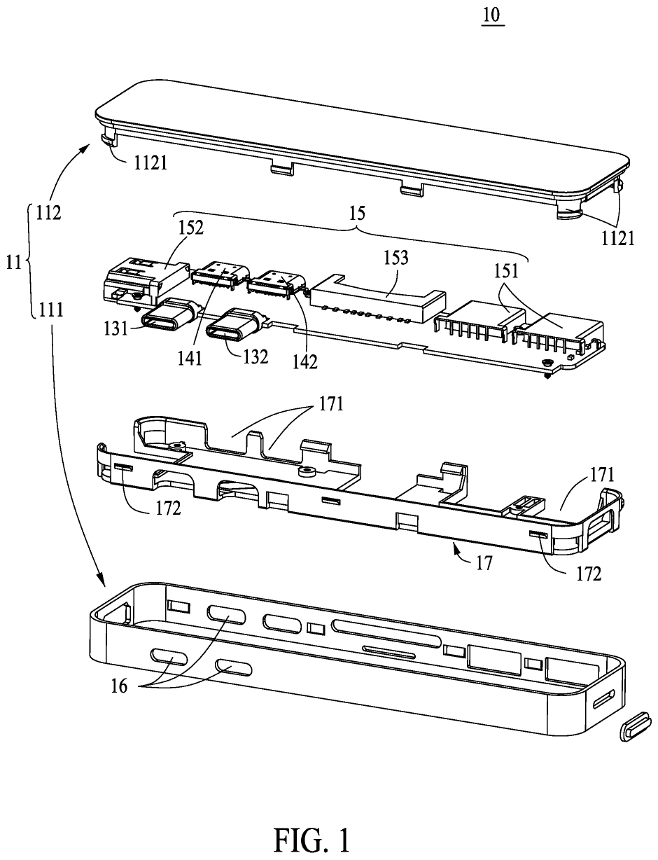

FIG. 1 is exploded structural schematic diagram I of a dual-interface reversible plug-in power source and data docking station provided by an embodiment of the present invention;

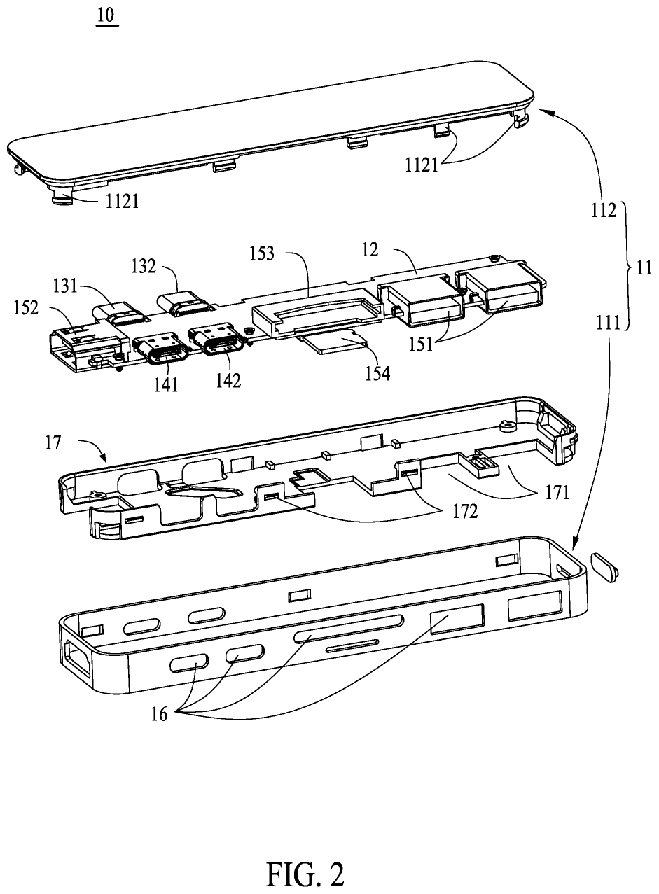

FIG. 2 is exploded structural schematic diagram II of a dual-interface reversible plug-in power source and data docking station provided by an embodiment of the present invention; and

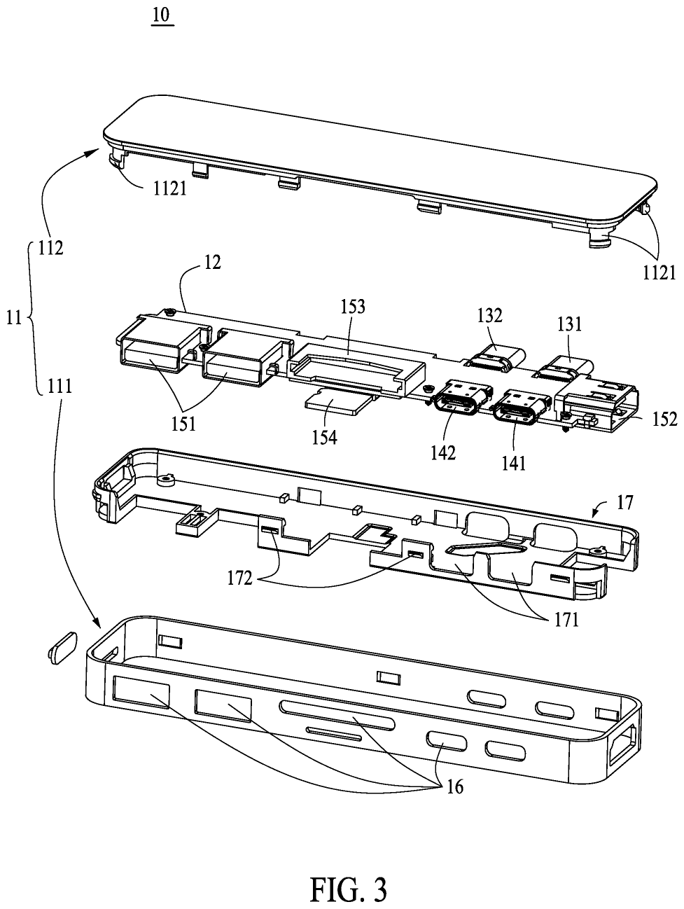

FIG. 3 is exploded structural schematic diagram III of a dual-interface reversible plug-in power source and data docking station provided by an embodiment of the present invention.

In the figures, reference numerals in the figures:

10—dual-interface reversible plug-in power source and data docking station; 11—case; 12—circuit board; 131—first Type-C male interface; 132—second Type-C male interface; 141—first Type-C female interface; 142—second Type-C female interface; 15—interface group; 16—opening; 151—USB interface; 152—HDMI interface; 153—SD card interface; 154—Micro SD card interface; 111—bottom case; 112—upper cover; 17—fixing frame; 171—notch; 1121—barb; and 172—barb slot.

### EMBODIMENTS OF THE INVENTION

### Detailed Description of Embodiments

In order to make the technical problems to be solved, the technical solutions and the beneficial effects of the present invention clearer, the present invention is further illustrated in detail below in conjunction with the accompanying drawings and embodiments. It should be understood that the specific embodiments described here are merely illustrative of the present invention but are not intended to limit the present invention.

It should be noted that when an element is referred to as being “fixed to” or “arranged at” a further element, it can be directly located on the further element or indirectly located on the further element. When an element is referred to as being “connected to” a further element, it can be directly connected to the further element or indirectly connected to the further element.

It should be understood that orientation or positional relationship indicated by the terms “length”, “width”, “upper”, “lower”, “front”, “rear”, “left”, “right”, “vertical”, “horizontal”, “top”, “bottom”, “inside”, “outside” and the like is based on the orientation or positional relationship as shown in the drawings, and is merely for the convenience of describing the present invention and simplifying the description, rather than indicating or implying that the indicated apparatus or element must have a particular orientation or be configured and operated in a particular orientation, which is thus not to be construed as limiting the present invention.

In addition, the terms “first” and “second” are for descriptive purposes only and should not be understood as indicating or implying relative importance or implicitly indicating the number of technical features indicated. Thus, the features defined with “first” and “second” can explicitly or implicitly include one or more of the features. In the description of the present invention, the meaning of “a plurality of” is two or more unless clearly and specifically defined otherwise.

Referring to FIGS. 1 to 3 together, the present invention provides a dual-interface reversible plug-in power source and data docking station 10, comprising a case 11 having an inner cavity and a circuit board 12 arranged in the inner cavity, wherein the circuit board 12 is provided with a first side and a second side opposite to or adjacent to the first side; the first side is provided with a first Type-C male interface 131 configured to be connected to one of interfaces of the MacbookPro and a second Type-C male interface 132 which are arranged side by side at an interval from the first Type-C male interface 131 and configured to be connected to the other interface of the MacbookPro; the second side is provided with a first Type-C female interface 141 and a second Type-C female interface 142 respectively opposite to the first Type-C male interface 131 and the second Type-C male interface 132, the second side is further provided with an interface group 15 for charging and/or data transmission for an external electronic product, and the first Type-C male interface 131 and the second Type-C male interface 132 are exposed outside the case 11; and the case 11 is provided with a plurality of openings 16 respectively corresponding to the first Type-C female interface 141, the second Type-C female interface 142 and the interface group 15 on a one-to-one basis.

Referring to FIGS. 1 to 3 together, when the dual-interface reversible plug-in power source and data docking station 10 described above is configured to be connected to a MacbookPro, the first Type-C male interface 131 and the second Type-C male interface 132 located on the first side of the circuit board 12 can be respectively connected to the two interfaces of the MacbookPro, and the first Type-C male interface 131 and the second Type-C male interface 132 can be connected to the two interfaces of the MacbookPro regardless of whether normal plug-in or reverse plug-in is used Moreover, since the two interfaces of the MacbookPro are blocked by the dual-interface reversible plug-in power source and data docking station 10 so that the user cannot use the two original interfaces of the MacbookPro for charging, video communication or data communication, the dual-interface reversible plug-in power source and data docking station 10 is provided with the first Type-C female interface 141 and the second Type-C female interface 142 for extension while converting the first Type-C male interface 131 and the second Type-C male interface 132 into other interfaces such as the interface group 15, and is externally connected to an external electronic product through the first Type-C female interface 141 and the second Type-C female interface 142 for charging, video communication or data communication. In this way, when the dual-interface reversible plug-in power source and data docking station 10 described above is used by a user for charging, video communication or data communication for an external electronic product, it not only has a new Type-C female interface function and is also compatible with the old interface function, e.g., using the interface group 15.

It should be additionally noted that the first Type-C male interface 131, the second Type-C male interface 132, the first Type-C male interface 131 and the second Type-C male interface 132 are all in bidirectional transmission; the first Type-C female interface 141 is configured to be connected to a device with Type-C interfaces and support USB data transmission; and the second Type-C female interface 142 is configured to be connected to the device with Type-C interfaces and support PD charging function, USB data transmission and DP data transmission (DisplayPort, which is a high-definition digital display interface standard, referred to as DP for short).

Referring to FIGS. 1 to 3 together, in order to implement the function extension of the dual-interface reversible plug-in power source and data docking station 10 in a better way, the interface group 15 comprises a USB interface 151, an HDMI interface 152 (High Definition Multimedia Interface, referred to as HDMI for short) configured to be connected to a display device, an SD card interface 153 for reading an SD card (SecureDigital, referred to as SD for short), and a Micro SD card interface 154 for reading a Micro SD card. Of course, the number of USB interfaces 151 is set to at least one. The type of the USB interface 151 may be USB2.0, USB3.0, USB-C or USB3.1 Gen1*2, and when the USB interface 151 is USB3.1 Gen1*2, it supports 5 Gb high-speed transmission. Thus, a mobile phone, a tablet or a PC computer may be connected through the USB interface 151; a display device, such as a high-definition display, is connected through the HDMI interface 152, specifically, the HDMI interface 152 supports HDMI 2.0a and supports 4K/30 Hz resolution; and the information of an SD card is read through the SD card interface 153, of course, the SD card includes a Micro SD card.

Specifically, the case 11 comprises a bottom case 111, and the bottom case 111 comprises a bottom portion and a side wall extending along the periphery of the bottom portion, the bottom portion and the side wall are enclosed to form the inner cavity, an upper end of the side wall is detachably connected to an upper cover 112, and the openings 16 are provided in the side wall.

Referring to FIGS. 1 to 3 together, in order to facilitate installing and fixing the circuit board 12 into the inner cavity, a fixing frame 17 is arranged in the inner cavity, and the circuit board 12 is installed on the fixing frame 17.

Specifically, in order to allow the circuit board 12 to be installed and fixed to the fixing frame 17 in a better way, the fixing frame 17 comprises a bottom plate and a side frame wall extending along the periphery of the bottom plate, and the side frame wall is provided with a plurality of notches 171 respectively corresponding to the opening 16 on a one-to-one basis, and the circuit board 12 is installed in a space enclosed by the bottom plate and the side frame wall.

Referring to FIGS. 1 to 3 together, specifically, in order to assemble and disassemble the case 11 more conveniently, the periphery of the upper cover 112 is provided with a plurality of barbs 1121 arranged at intervals, and the side frame wall is provided with a plurality of barb slots 172 respectively corresponding to and matching the barbs 1121 on a one-to-one basis. Thus, the assembly and disassembly between the bottom case 111 and the upper cover 112 is achieved by the matching between the barbs 1121 and the barb slots 172.

In order to make full use of the installation space on the circuit board 12, the circuit board 12 has an elongated shape, the first side is arranged opposite the second side, the first Type-C female interface 141, the second Type-C female interface 142 and the interface group 15 are all arranged on the second side, and the case 11 has an elongated shape. Thus, the dual-interface reversible plug-in power source and data docking station 10 described above can be made small in size and integrates multiple functions of charging and data communication.

Referring to FIGS. 1 to 3 together, in order to facilitate the implementation of charging and data communication functions of the dual-interface reversible plug-in power source and data docking station 10 described above, a main control chip, a high-definition decoding chip, a power source management chip, a high-frequency transformer and a power component are arranged at intervals on the circuit board 12.

In order to further implement the function extension of the dual-interface reversible plug-in power source and data docking station 10 described above, the interface group 15 further comprises a VGA interface (Video Graphics Array, referred to as VGA for short), a DVI interface (Digital Visual Interface, referred to as DVI for short), a DP interface (DisplayPort, which is a high-definition digital display interface standard, referred to as DP for short), a Mini DP interface (English: Mini DisplayPort, which is a high-definition digital display interface standard , referred to as small DP for short) or a network interface.

The above embodiments are merely preferred embodiments of the present invention but not intended to limit the present invention, and any modifications, equivalent replacements, improvements, etc. made within the spirit and principles of the present invention should be included within the scope of protection of the present invention.

What is claimed is:

1. A dual-interface reversible plug-in power source and data docking station, characterized by comprising a case having an inner cavity and a circuit board arranged in the inner cavity, wherein the circuit board is provided with a first side and a second side opposite or adjacent to the first side; the first side is provided with a first Type-C male interface configured to be connected to one of interfaces of a MacbookPro, and a second Type-C male interface which is arranged side by side at an interval from the first Type-C male interface and configured to be connected to the other interface of the MacbookPro; the second side is provided with a first Type-C female interface and a second Type-C female interface which are respectively opposite the first Type-C male interface and the second Type-C male interface, and the second side is further provided with an interface group for charging and/or data transmission for an external electronic product; the first Type-C male interface and the second Type-C male interface are exposed outside the case; and the case is provided with a plurality of openings respectively corresponding to the first Type-C female interface, the second Type-C female interface and the interface group on a one-to-one basis.

2. The dual-interface reversible plug-in power source and data docking station of claim 1, characterized in that the interface group comprises a USB interface, an HDMI interface configured to be connected to a display device, an SD card interface for reading an SD card, and a Micro SD card interface for reading a Micro SD card.

3. The dual-interface reversible plug-in power source and data docking station of claim 1, characterized in that the case comprises a bottom case, which comprises a bottom portion and a side wall extending along the periphery of the bottom portion, wherein the bottom portion and the side wall are enclosed to form the inner cavity, an upper end of the side wall is detachably connected to an upper cover, and the openings are provided in the side wall.

4. The dual-interface reversible plug-in power source and data docking station of claim 3, characterized in that a fixing frame is arranged in the inner cavity, and the circuit board is installed on the fixing frame.

5. The dual-interface reversible plug-in power source and data docking station of claim 4, characterized in that the fixing frame comprises a bottom plate and a side frame wall extending along the periphery of the bottom plate, wherein the side frame wall is provided with a plurality of notches respectively corresponding to the opening on a one-to-one basis, and the circuit board is installed in a space enclosed by the bottom plate and the side frame wall.

6. The dual-interface reversible plug-in power source and data docking station of claim 5, characterized in that the periphery of the upper cover is provided with a plurality of barbs arranged at intervals, and the side frame wall is provided with a plurality of barb slots respectively corresponding to and matching the barbs on a one-to-one basis.

7. The dual-interface reversible plug-in power source and data docking station according to claim 2, characterized in that the number of the USB interfaces is set to at least one.

8. The dual-interface reversible plug-in power source and data docking station according to claim 1, characterized in that the case has an elongated shape.

9. The dual-interface reversible plug-in power source and data docking station according to claim 1, characterized in that a main control chip, a high-definition decoding chip, a power source management chip, a high-frequency transformer and a power component are arranged at intervals on the circuit board.

10. The dual-interface reversible plug-in power source and data docking station according to claim 1, characterized in that the interface group further comprises a VGA interface, a DVI interface, a DP interface, a Mini DP interface or a network interface.

11. The dual-interface reversible plug-in power source and data docking station according to claim 2, characterized in that the type of the USB interface is USB2.0, USB3.0, USB-C or USB3.1.

12. The dual-interface reversible plug-in power source and data docking station according to claim 1, characterized in that the first Type-C male interface, the second Type-C male interface, the first Type-C male interface and the second Type-C male interface are all in bidirectional transmission.

13. The dual-interface reversible plug-in power source and data docking station according to claim 1, characterized in that the first Type-C female interface is connected to a device with Type-C interfaces and configured to support USB data transmission, and the second Type-C female interface is connected to the device with Type-C interfaces and configured to support a PD charging function.
